(19) United States
(12) Patent Application Publication
(10) Pub. No.: US 2025/0180990 A1
(43) Pub. Date: Jun. 5, 2025

(54) PHOTOSENSITIVE SURFACE TREATING AGENT, LAMINATE, PATTERN FORMATION SUBSTRATE, TRANSISTOR, PATTERN FORMING METHOD AND METHOD OF PRODUCING TRANSISTOR

(71) Applicant: NIKON CORPORATION, Tokyo (JP)

(72) Inventors: Yusuke KAWAKAMI, Yokohama-shi (JP); Kazuo YAMAGUCHI, Yokohama-shi (JP); Michiko ITOU, Yokohama-shi (JP)

(21) Appl. No.: 19/051,534

(22) Filed: Feb. 12, 2025

Related U.S. Application Data
(63) Continuation of application No. PCT/JP2023/030088, filed on Aug. 22, 2023.

(30) Foreign Application Priority Data
Aug. 22, 2022 (JP) 2022-131901

(51) Int. Cl. G03F 7/039; C07F 7/18; C08F 20/36; C23C 18/16; H01L 21/288

(52) U.S. Cl. CPC G03F 7/039; C07F 7/1804; C08F 20/36; C23C 18/1608; H01L 21/288

(57) ABSTRACT

A photosensitive surface treating agent containing a compound represented by the following Formula (M1). In Formula (M1), R¹ is a linear, branched or cyclic alkyl group having 1 to 6 carbon atoms, Y¹ is a linear or branched alkylene group having 1 to 4 carbon atoms or a single bond, and the terminal carbon atom of the alkyl group for R¹ may be bonded to a carbon atom constituting the alkylene group for Y¹, and R¹ and Y¹ may form a ring. R² is a hydrogen atom or an alkyl group having 1 to 6 carbon atoms, R³ and R⁴ are each independently an alkyl group having 1 to 3 carbon atoms, n0 is an integer of 0 or more, and X is a halogen atom or an alkoxy group.

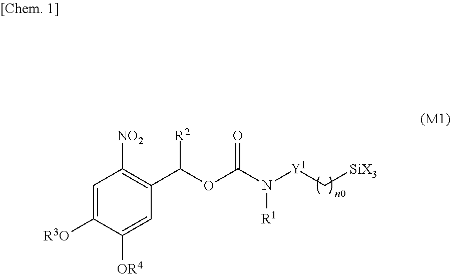

### TECHNICAL FIELD

The present invention relates to a photosensitive surface treating agent, a laminate, a pattern formation substrate, a transistor, a pattern forming method and a method of producing a transistor.

Priority is claimed on Japanese Patent Application No. 2022-131901, filed Aug. 22, 2022, the content of which is incorporated herein by reference.

### BACKGROUND ART

In recent years, in the production of microdevices such as semiconductor elements, integrated circuits, and organic EL display devices, a method of forming patterns with different surface properties on a substrate, and preparing a microdevice using the difference in the surface properties has been proposed.

As a pattern forming method using the difference in the surface properties on a substrate, for example, there is a method of forming a region in which chemically active substituents are generated on a part of the substrate. By this method, a metal material, an organic material or an inorganic material can be adhered to a part of the substrate.

An electroless plating treatment is a technique for adhering a metal material onto a substrate to form a metal film. For example, Patent Document 1 discloses a technique for forming a fine wiring by an electroless plating treatment. Specifically, Patent Document 1 discloses that a catalyst activation layer and a photoresist are used to perform photo-patterning by etching or lift-off after one surface is plated.

### CITATION LIST

### Patent Document

Patent Document 1: Japanese Unexamined Patent Application, First Publication No. 2006-2201

### SUMMARY OF INVENTION

A first aspect of the present invention is a photosensitive surface treating agent containing a compound represented by the following Formula (M1).

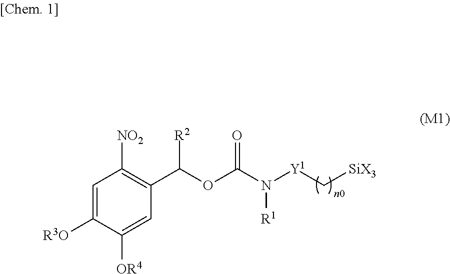

(in Formula (M1), R¹ is a linear, branched or cyclic alkyl group having 1 to 6 carbon atoms, Y¹ is a linear or branched alkylene group having 1 to 4 carbon atoms or a single bond, and the terminal carbon atom of the alkyl group for R¹ may be bonded to a carbon atom constituting the alkylene group for Y¹, and R¹ and Y¹ may form a ring,
   R² is a hydrogen atom or an alkyl group having 1 to 6 carbon atoms, R³ and R⁴ are each independently an alkyl group having 1 to 3 carbon atoms, n0 is an integer of 0 or more, and X is a halogen atom or an alkoxy group).

### BRIEF DESCRIPTION OF DRAWINGS

FIG. 1 Schematic views illustrating a pattern forming method of the present embodiment.

FIG. 2 Schematic views illustrating a method of producing a transistor according to the present embodiment.

FIG. 3A Overall images of resolution charts drawn on a polyimide substrate and a quartz substrate.

FIG. 3B Optical microscope images of resolution charts drawn on a quartz substrate.

FIG. 3C Optical microscope images of L/S=3/3 to 10/10 μm drawn on a quartz substrate.

FIG. 3D An optical microscope image of L/S=1/1 to 8/8 μm drawn on a quartz substrate.

### DESCRIPTION OF EMBODIMENTS

### <Photosensitive Surface Treating Agent>

A photosensitive surface treating agent of the present embodiment contains a compound represented by the following Formula (M1).

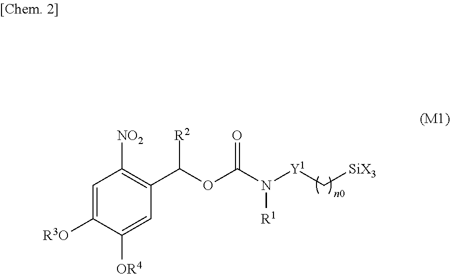

(in Formula (M1), R¹ is a linear, branched or cyclic alkyl group having 1 to 6 carbon atoms, Y¹ is a linear or branched alkylene group having 1 to 4 carbon atoms or a single bond, and the terminal carbon atom of the alkyl group for R¹ may be bonded to a carbon atom constituting the alkylene group for Y¹, and R¹ and Y¹ may form a ring,
   R² is a hydrogen atom or an alkyl group having 1 to 6 carbon atoms, R³ and R⁴ are each independently an alkyl group having 1 to 3 carbon atoms, n0 is an integer of 0 or more, and X is a halogen atom or an alkoxy group).

### (R¹)

In Formula (M1), R¹ is a linear, branched or cyclic alkyl group having 1 to 6 carbon atoms. Examples of alkyl groups having 1 to 4 carbon atoms include a methyl group, ethyl group, propyl group, isopropyl group, n-butyl group, and tert-butyl group.

### (Y¹)

In Formula (M1), Y¹ is a linear or branched alkylene group having 1 to 4 carbon atoms. Examples of Y¹ include a methylene group [—CH₂—], an ethylene group [—(CH₂)₂—], a trimethylene group [—(CH₂)₃—], and a tetramethylene group [—(CH₂)₄—]. In addition, examples of Y¹ include —CH(CH₃)—, —CH(CH₂CH₃)—, —C(CH₃)₂—, and —C(CH₃)(CH₂CH₃)—.

In Formula (M1), Y¹ may be a single bond.

The terminal carbon atom of the alkyl group for R¹ may be bonded to a carbon atom constituting the alkylene group for Y¹, and R¹ and Y¹ may form a ring.

In this case, the ring formed by R¹ and Y¹ is, for example, a piperidyl group.

That is, Formula (M1) may be the following Formula (M1)-A.

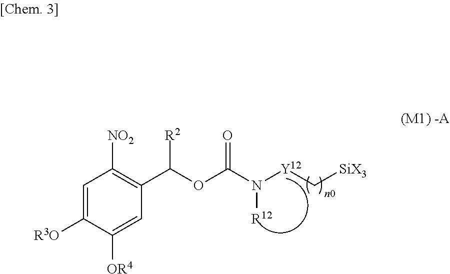

(in Formula (M1), R¹ is a linear, branched or cyclic alkyl group having 1 to 6 carbon atoms, Y¹² is a linear or branched alkylene group having 1 to 4 carbon atoms, and the terminal carbon atom of the alkyl group for R¹² is bonded to a carbon atom constituting the alkylene group for Y¹² to form a ring,
   R² is a hydrogen atom or an alkyl group having 1 to 6 carbon atoms, R³ and R⁴ are each independently an alkyl group having 1 to 3 carbon atoms, n0 is an integer of 0 or more, and X is a halogen atom or an alkoxy group).

### (R²)

In Formula (M1), R² is a hydrogen atom or an alkyl group having 1 to 6 carbon atoms. Examples of alkyl groups having 1 to 6 carbon atoms include a methyl group, ethyl group, propyl group, isopropyl group, n-butyl group, tert-butyl group, hexyl group, and cyclohexyl group. Among these, an isopropyl group or a cyclohexyl group is preferable, and an isopropyl group is more preferable.

(R³ and R⁴)

R² and R³ are each independently an alkyl group having 1 to 3 carbon atoms. Examples of alkyl groups having 1 to 3 carbon atoms include a methyl group, ethyl group, and propyl group, and a methyl group or an ethyl group is preferable, and a methyl group is more preferable.

(n0)

In Formula (M1), n0 is an integer of 0 or more, is preferably 1 or more and 6 or less, and more preferably 1 or more and 4 or less.

(X) In Formula (M1), X is a halogen atom or an alkoxy group. Examples of halogen atoms represented by X include a fluorine atom, a chlorine atom, a bromine atom and an iodine atom.

X is preferably an alkoxy group. Examples of alkoxy groups for X include —O—(CH₃), and —O—(CH₂)ₙ(CH₃). n is a natural number of 1 to 3.

Specific examples of compounds represented by Formula (M1) are shown below.

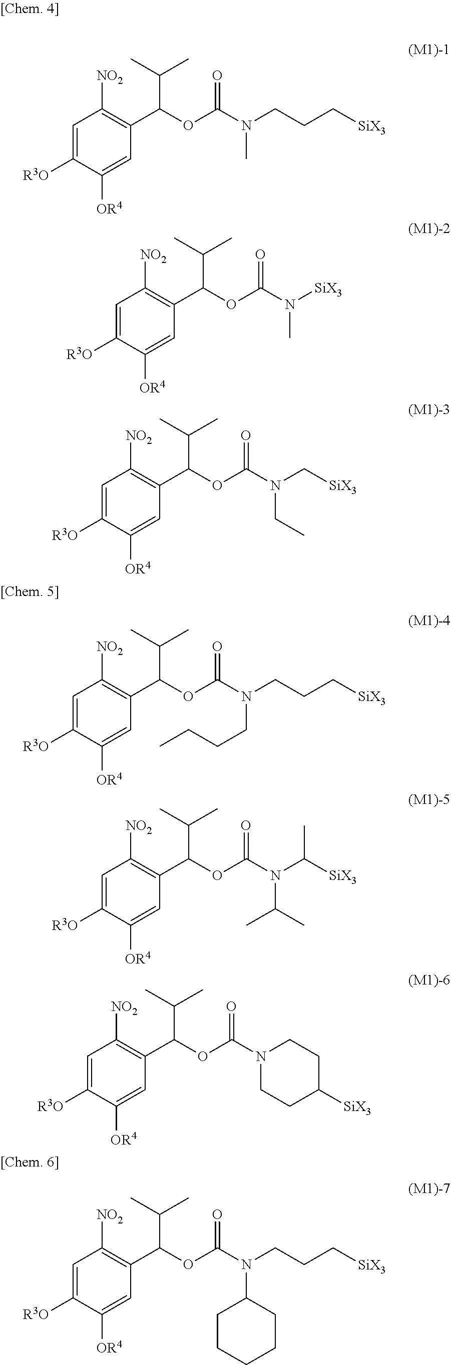

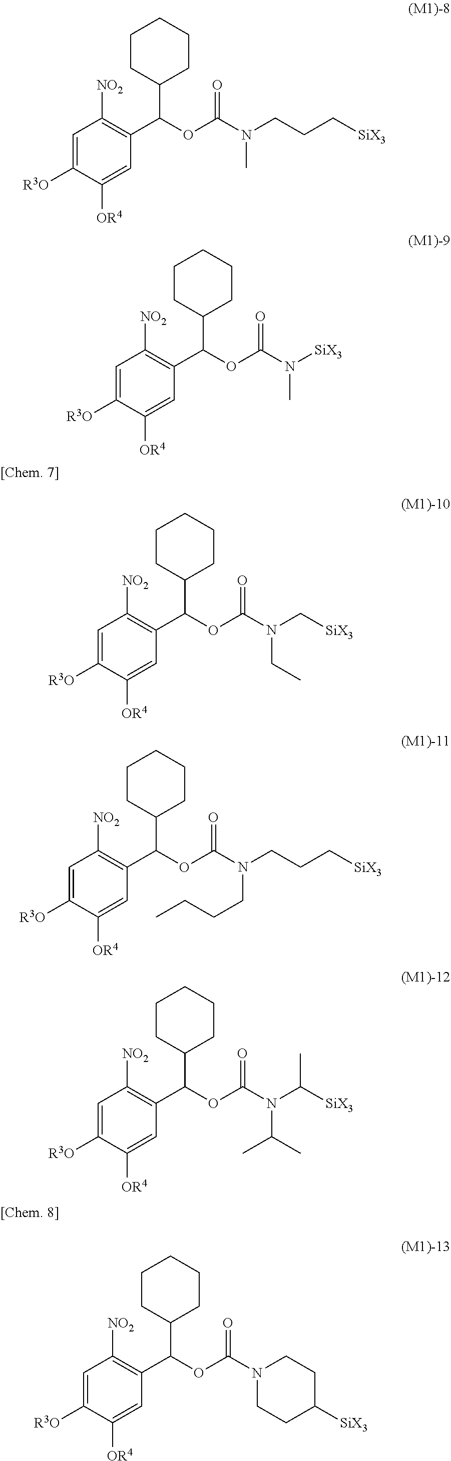

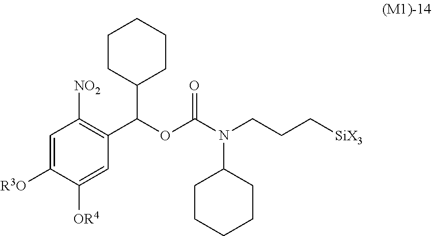

When a photosensitive surface treating agent containing the compound represented by Formula (M1) is applied onto a substrate and light is emitted, a nitrobenzyl group is eliminated, SiX₃ adheres to the substrate, and at the same time, amines are generated on the surface of the substrate. Metal materials, organic materials or inorganic materials can be adhered to a portion in which amines are generated. The amines generated from the compound represented by Formula (M1) are primary amines (—NH₂) or secondary amines (—NH—).

In the compound represented by Formula (M1), R¹ is a linear, branched or cyclic alkyl group having 1 to 6 carbon atoms. Therefore, it is bulkier than the compound in which the group corresponding to R¹ is a hydrogen atom, and the photolysis rate at which the nitrobenzyl group is eliminated is improved.

In addition, in the compound represented by Formula (M1), since R¹ has the above structure, a reverse reaction after photolysis is unlikely to occur. The reverse reaction after photolysis is a reaction in which the eliminated nitrobenzyl group bonds again after photolysis.

According to the photosensitive surface treating agent of the present embodiment, when a metal material is disposed in the amine-generated portion formed on the surface of the substrate, for example, a fine metal pattern with a line width of 3 μm or less can be formed on the surface of the substrate without using a photoresist step, a developing step, or an etching step.

One aspect of the present invention is a photosensitive surface treating agent containing a polymer compound represented by the following Formula (P1).

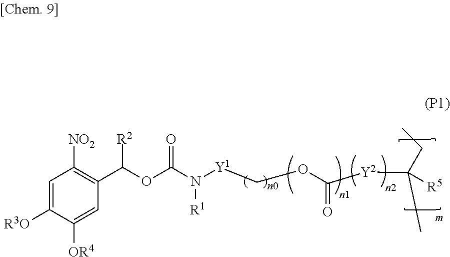

(in Formula (P1), R¹ is a linear, branched or cyclic alkyl group having 1 to 6 carbon atoms, Y¹ is a linear or branched alkylene group having 1 to 4 carbon atoms or a single bond, Y² is a group obtained by removing two hydrogen atoms from an aromatic ring having 6 to 15 carbon atoms, and the terminal carbon atom of the alkyl group for R¹ may be bonded to a carbon atom constituting the alkylene group for Y¹, and R¹ and Y¹ may form a ring,
   R² is a hydrogen atom or an alkyl group having 1 to 6 carbon atoms, R³ and R⁴ are each independently an alkyl group having 1 to 3 carbon atoms, R⁵ is a hydrogen atom or a methyl group, n0, n1, and n2 are each independently an integer of 0 or more, and m is a natural number).

In Formula (P1), the descriptions for R¹, R², R³, R⁴, R⁵, Y¹, Y², n0, n1, and n2 are the same as above, and m is a natural number.

In the polymer compound represented by Formula (P1), a substituent represented by the following Formula (1x) is preferably bonded to at least one terminal of the main chain. In the following Formula (1x), * indicates the bonding site with the terminal of the main chain of the polymer compound represented by Formula (P1).

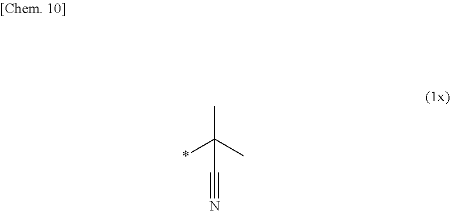 [SMILES: *C(C)(C)C#N]

An example of a polymer compound (P1)-A in which a substituent represented by Formula (1x) is bonded to the terminal of the main chain of the polymer compound represented by Formula (P1) is shown below.

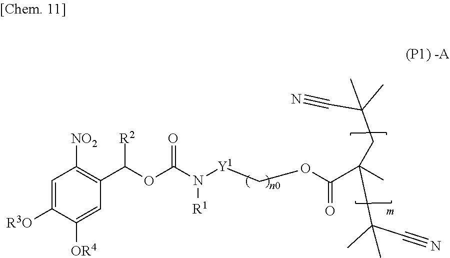

Other specific examples of polymer compounds represented by Formula (P1)-A are shown below.

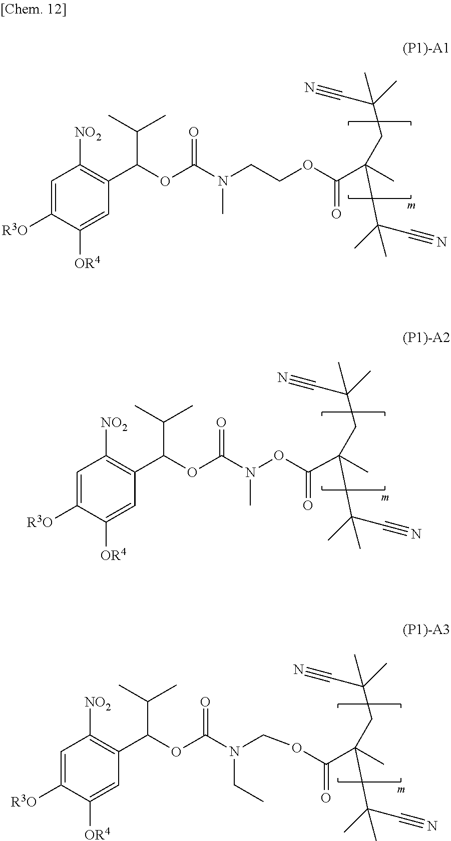

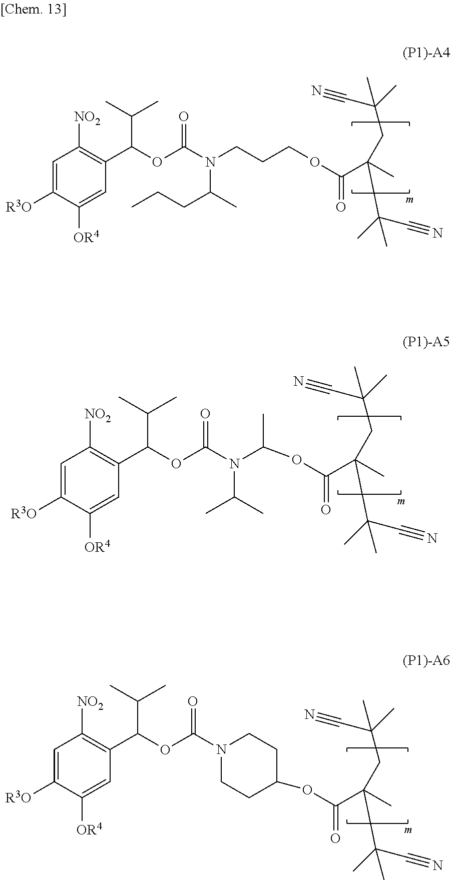

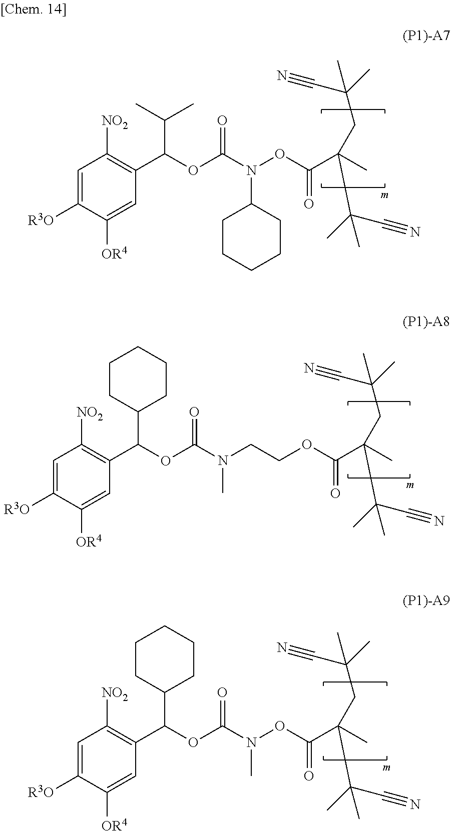

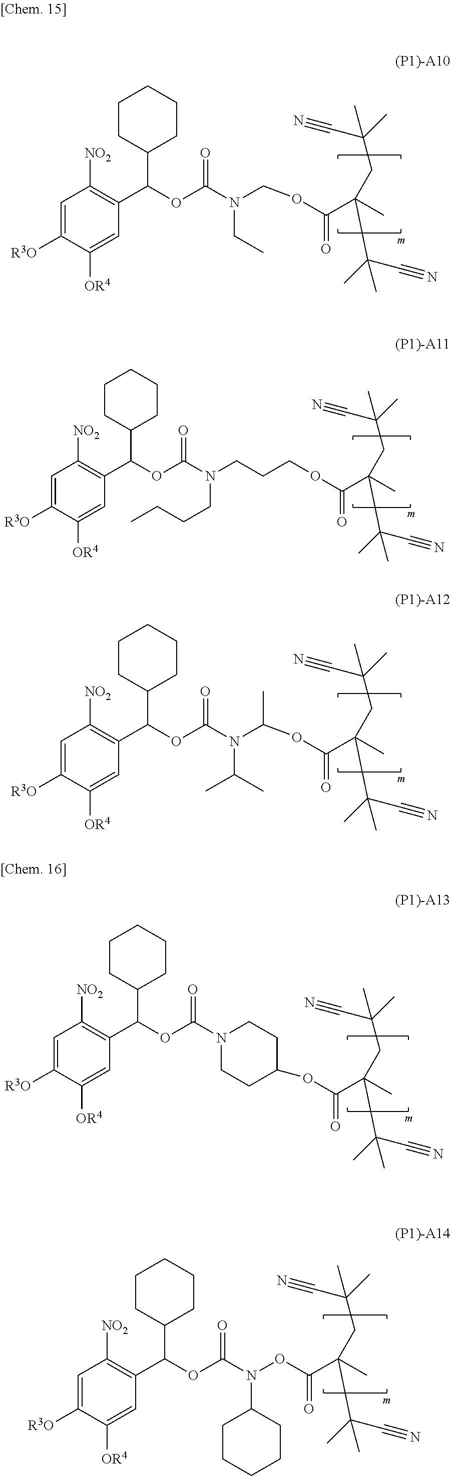

The number average molecular weight of the polymer compound represented by Formula (P1) is preferably 300 to 100,000, and more preferably 2,000 to 40,000. This can be measured by gel permeation chromatography (GPC) or matrix-assisted laser desorption/ionization time-of-flight mass spectrometry (MALDI-Tof-MS).

### <Method of Producing Compound>

A compound represented by Formula (M1) can be produced by the following method.

In description of the following production method, the descriptions for respective symbols in the formula are the same as above.

The compound represented by Formula (M1) can be produced by a method including a step of synthesizing an active intermediate from an alcohol and reacting it with a primary or secondary amine.

Examples of active intermediates include an active intermediate obtained by activating benzyl alcohol with carbonyl chloride as shown in the following Reaction Formula (R)-1 (for example, carboxylic acid chloride), an active intermediate obtained by activating benzyl alcohol with carbonyl imidazole as shown in the following Reaction Formula (R)-2 (for example, oxycarbonyl imidazole), and an active intermediate obtained by activating benzyl alcohol with carbonyloxysuccinimide as shown in the following Reaction Formula (R)-4 (for example, oxycarbonyloxysuccinimide). In the following reactions (R)-1, (R)-2, and (R)-4, a method of producing a compound represented by Formula (M1) using a secondary amine compound containing R¹ is shown, but a compound represented by Formula (M1) may be produced by forming a carbamate using a primary amine compound not containing R¹ and then introducing R¹ onto a nitrogen atom according to the following production method.

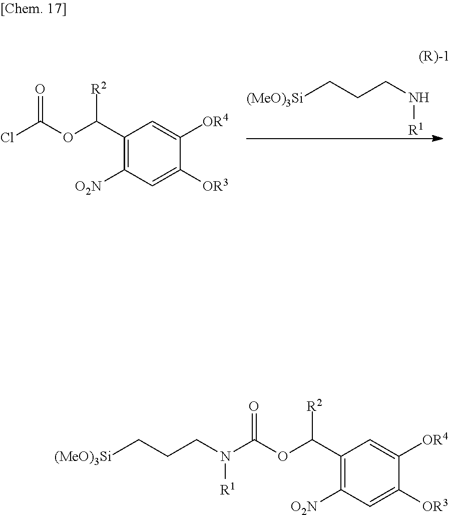

Examples of starting substances shown in the reaction (R)-1 include a compound (R² is H) of CAS No. 42855-00-5 and a compound of CAS No. 363135-50-6 (R² is Me).

A method of synthesizing a compound (R² is H) of CAS No. 42855-00-5 is disclosed in Chemical Science (2016), 7 (3), 1891-1895. A compound in which R² is a desired alkyl group can be produced by a method similar to that disclosed in Chemical Science (2016), 7 (3), 1891-1895.

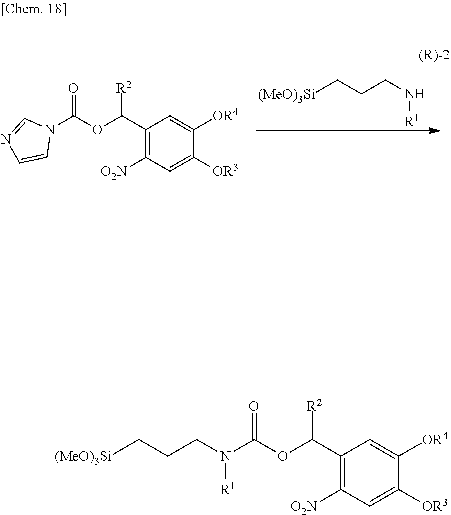

Examples of starting substances shown in the reaction (R)-2 include a compound (R² is H) of CAS No. 188305-03-5 and a compound of CAS No. 2097130-00-0 (R² is Me).

A method of synthesizing a compound (R² is Me) of CAS No. 2097130-00-0 is disclosed in Organic Letters (2017), 19 (7), 1618-1621. A compound in which R² is a desired alkyl group can be produced by a method similar to that disclosed in Organic Letters (2017), 19 (7), 1618-1621.

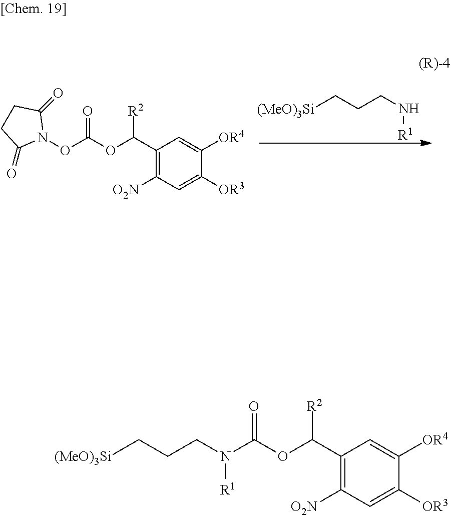

In addition, a compound represented by Formula (M1) can be produced by reacting an active intermediate obtained by activating benzyl alcohol with formic acid chloride, a carbonate or the like with an amino compound containing a terminal double bond to form nitrobenzyl carbamate and then reacting it with a metal catalyst or a trialkoxysilane such as trimethoxyhydrosilane.

The following Reaction Formula (R)-5 is an example in which a compound containing an allyl group is used as an amino compound containing a terminal double bond.

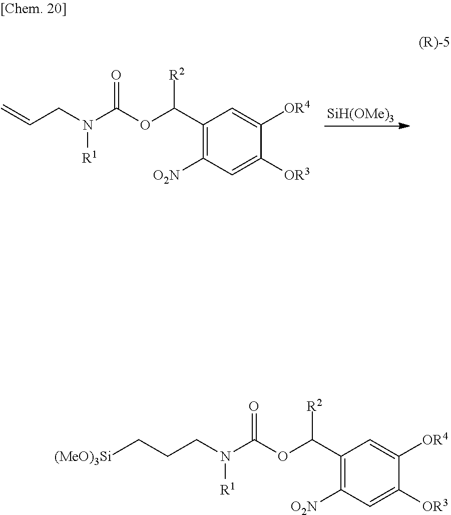

The following Reaction Formula (R)-6 is an example in which a compound containing a vinyl group is used as an amino compound containing a terminal double bond.

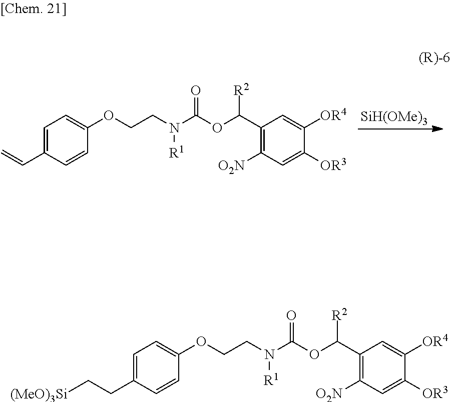

A compound represented by Formula (M1) can be produced by reacting an active intermediate obtained by activating benzyl alcohol with formic acid chloride, a carbonate or the like with an aminosilane compound containing a primary amine to form nitrobenzyl carbamate and then reacting it with an alkyl compound containing R¹ and iodine or a leaving group.

The following Reaction Formula (R)-7 is an example of a reaction with a compound containing R¹ and iodine.

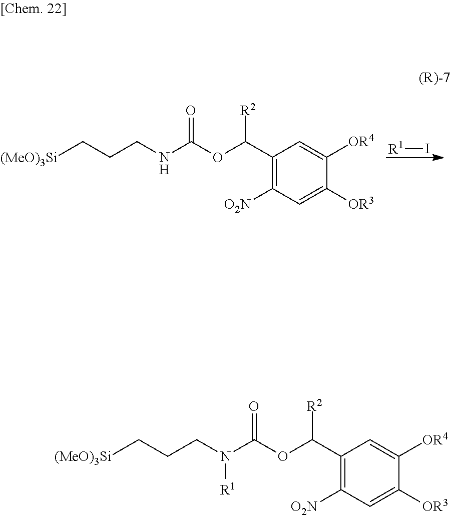

The following Reaction Formula (R)-8 is an example of a reaction with a compound containing R¹ and a tosyloxy group. Here, the tosyloxy group is eliminated during the reaction.

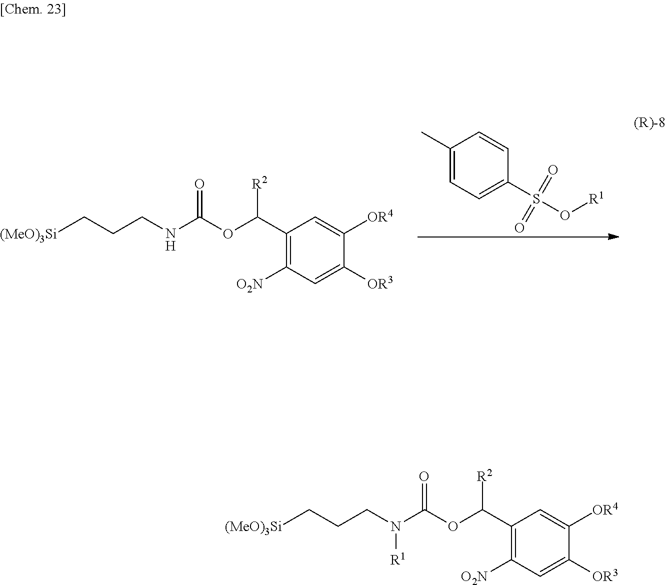

A carbamate compound not containing R¹ can be produced by reacting benzyl alcohol with a compound containing an isocyanate. The following Reaction Formula (R)-10 is an example in which benzyl alcohol is reacted with an isocyanate compound containing a trialkoxysilyl group. A compound represented by Formula (M1) can be produced by introducing R¹ into the carbamate compound not containing R¹ synthesized in this manner by the production method.

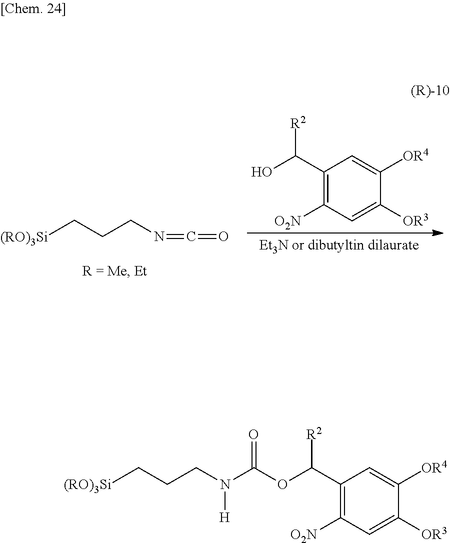

### <Method of Producing Polymer Compound>

A compound represented by Formula (P1) can be produced by the following method.

In description of the following production method, the descriptions for respective symbols in the formula are the same as above.

A P1 precursor, which is a precursor of the polymer compound represented by Formula (P1), can be produced by reacting an active intermediate obtained by activating benzyl alcohol with carbonyl chloride as shown in the following Reaction Formula (PR)-1 with an amino methacrylate compound containing R¹.

A P1 precursor, which is a precursor of the polymer compound represented by Formula (P1), can be produced by reacting an active intermediate obtained by activating benzyl alcohol with carbonyloxyimidazole as shown in the following Reaction Formula (PR)-2 with an amino methacrylate compound containing R¹.

A P1 precursor, which is a precursor of the polymer compound represented by Formula (P1), can be produced by reacting an active intermediate obtained by activating benzyl alcohol with carbonyloxysuccinimide as shown in the following Reaction Formula (PR)-4 with an amino methacrylate compound containing R¹.

The following reaction shows a method of producing a compound represented by Formula (P1) using a secondary amine compound containing R¹. The method of producing a compound represented by Formula (P1) is not limited thereto, and a compound represented by Formula (P1) may be produced by forming a carbamate using a primary amine compound not containing R¹ and then introducing R¹ onto a nitrogen atom according to the following production method.

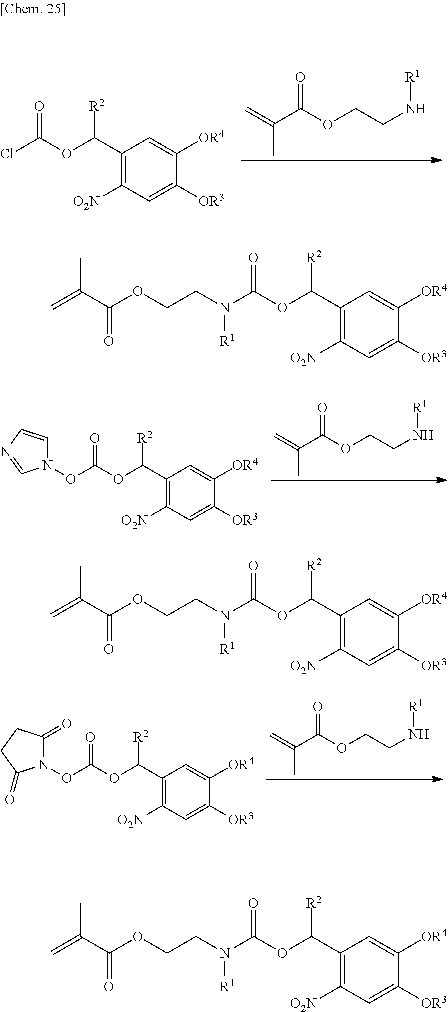

A P1 precursor, which is a precursor of the polymer compound represented by Formula (P1), can be produced by reacting an active intermediate obtained by activating benzyl alcohol with formic acid chloride, a carbonate or the like as shown in the following Reaction Formula (PR)-5 with an amino alcohol compound to form nitrobenzyl carbamate and then reacting it with methacrylic acid.

A P1 precursor, which is a precursor of the polymer compound represented by Formula (P1), can be produced by reacting an active intermediate obtained by activating benzyl alcohol with formic acid chloride, a carbonate or the like as shown in the following Reaction Formula (PR)-6 with an amino alcohol compound to form nitrobenzyl carbamate and then reacting it with methacrylic acid chloride.

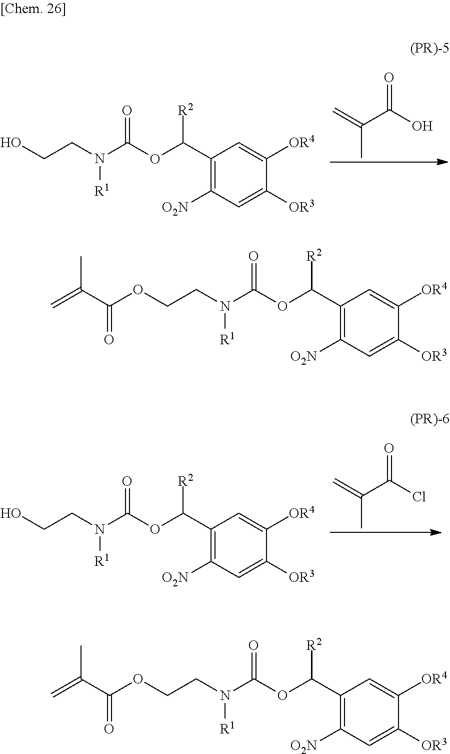

A P1 precursor, which is a precursor of the polymer compound represented by Formula (P1), can be produced by reacting an active intermediate obtained by activating benzyl alcohol with formic acid chloride, a carbonate or the like as shown in the following Reaction Formula (PR)-7 with an amino compound containing R¹ and a polymerizable functional group such as methacrylate.

Regarding a P1 precursor, which is a precursor of the polymer compound represented by Formula (P1), as shown in the following Reaction Formula (PR)-8, when the stability of a polymerizable functional group is reduced due to nucleophilicity of an amino group, the amino group is formed into a salt, a protecting group is introduced, an amine is activated in the reaction system, and thus the production of the P1 precursor is stabilized.

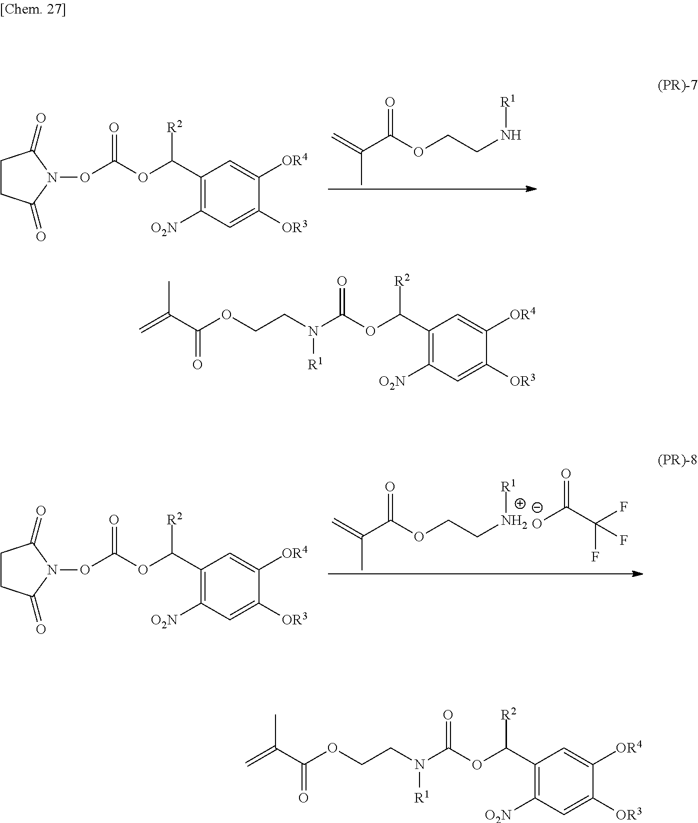

A carbamate compound not containing R¹ can be produced by reacting benzyl alcohol with a compound containing an isocyanate. The following Reaction Formula (R)-11 is an example in which benzyl alcohol is reacted with an isocyanate compound containing a trialkoxysilyl group. A compound represented by Formula (M1) can be produced by introducing R¹ into the carbamate compound not containing R¹ synthesized in this manner by the production method.

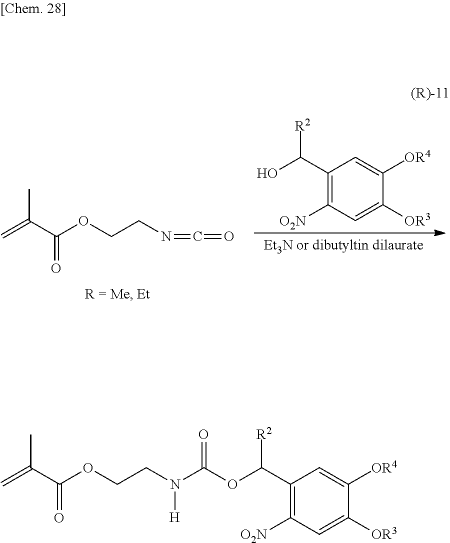

P1 is produced by reacting a P1 precursor containing a polymerizable functional group with various polymerization initiators such as a radical polymerization initiator and an anionic polymerization initiator.

Examples of this reaction are shown in the following Reaction Formulae (PR)-9 to (PR)-11.

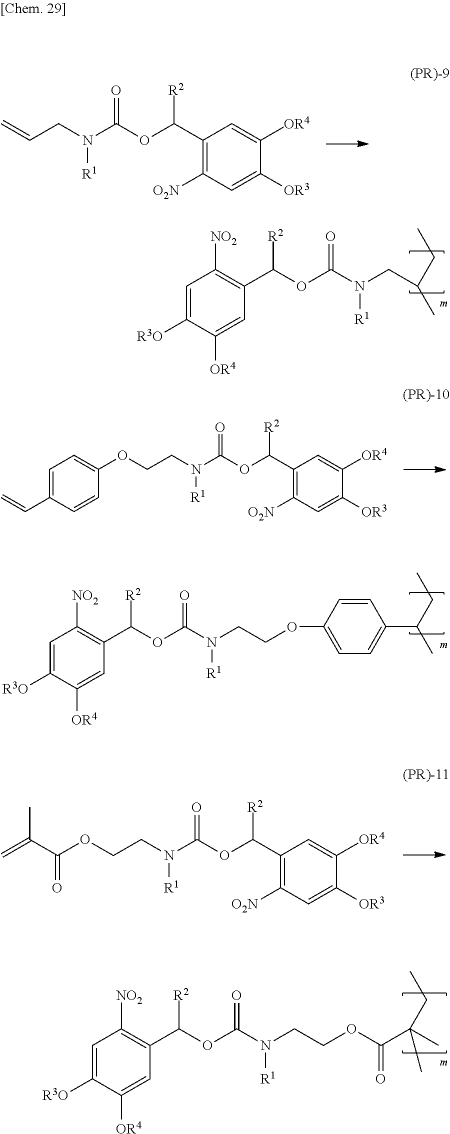

The polymerization of P1 is not particularly limited, and P1 may be polymerized by radical polymerization, anionic polymerization or the like. Among these, a radical polymerization method is preferable in consideration of ease of control and the like. Among radical polymerizations, controlled radical polymerization is more preferable for obtaining a certain solubility by controlling the molecular weight.

Examples of controlled radical polymerization methods include a chain transfer agent method and a living radical polymerization method, which is a type of living polymerization, and a living radical polymerization is more preferable because it is easy to control the molecular weight distribution. Here, examples of living radical polymerization methods include a nitroxy radical polymerization method (NMP), an atom transfer radical polymerization method (ATRP), and a reversible addition-fragmentation chain-transfer method (RAFT), and in consideration of the temperature and versatility, an atom transfer radical polymerization method (ATRP) is particularly preferable.

In addition to achieve a wide molecular weight distribution from a low-molecular weight to a high-molecular weight and obtaining a certain film formability, in consideration of the productivity and economical efficiency, radical polymerization involving a classical chain transfer reaction is preferable. Here, when radical polymerization is used, a conventionally known polymerization initiator can be appropriately used. In addition, the radical polymerization initiators may be used alone or two or more thereof may be used, or commercially available initiators may be used without change.

For example, an azo polymerization initiator, which is a compound that has an azo group (—N═N—) and generates a radical with N2, can be used. Specific examples thereof include azonitrile, azoester, azoamide, azoamidine, and azoimidazoline. More specific examples thereof include 2,2′-azobis(2-amidinopropane) dihydrochloride, 4,4′-azobis(4-cyanovaleric acid), 2,2′-bis(2-imidazolin-2-yl)-2,2′-azopropanedihydrochloride, 2,2′-bis(2-imidazolin-2-yl)-2,2′-azopropane, 2,2′-azobis [N-(2-hydroxyethyl)-2-methylpropionamide], 2,2′-azobisisobutyronitrile (AIBN), and 2,2′-azobis(2,4-dimethylvaleronitrile) (ADBN). Among these, 2,2′-azobisisobutyronitrile (AIBN) and 2,2′-azobis(2,4-dimethylvaleronitrile) (ADBN) are preferable, and 2,2′-azobisisobutyronitrile (AIBN) is particularly preferable.

In order to reduce the risk of dissolution and peeling in a plating bath or the like and secure the solubility during film formation, the number average molecular weight of the polymer compound synthesized in this manner is preferably 300 or more and 100,000 or less, which is sufficient for wet film formation, more preferably 1,000 or more and 90,000 or less, and still more preferably 2,000 or more and 40,000 or less. In addition, for the same reason, the peak of the molecular weight distribution is in the range of 1,000 or more and 90,000 or less, and more preferably 2,000 or more and 40,000 or less. This can be measured by gel permeation chromatography (GPC).

In one aspect of the present invention, the photosensitive surface treating agent contains the compound represented by Formula (M1).

In one aspect of the present invention, the photosensitive surface treating agent contains the polymer compound represented by Formula (P1).

In one aspect of the present invention, the photosensitive surface treating agent contains the compound represented by Formula (M1) and the polymer compound represented by Formula (P1).

In one aspect of the present invention, the photosensitive surface treating agent may contain a solvent. By dissolving it in a general organic solvent such as an alcohol-based solvent, an ester-based solvent, a hydrocarbon aromatic solvent, an amine-based solvent, a ketone-based solvent, a glycol ether-based solvent, or an ether-based solvent as a solvent, it can be used as a suitable surface treating agent.

Examples of alcohol-based solvents include isopropyl alcohol (IPA) and n-butyl alcohol (n-butanol).

Examples of ester-based solvents include ethyl acetate (EAC), butyl acetate (NBAC), n-propyl acetate (NPAC), and 3-methoxy-3-methylbutyl acetate.

Examples of hydrocarbon aromatic solvents include toluene, xylene, benzene, ethylbenzene, and trimethylbenzene.

Examples of amine-based solvents include N-methyl-2-pyrrolidone (NMP), dimethylformamide (DMF), and N,N-dimethylacetamide (DMAC).

Examples of ketone-based solvents include methyl ethyl ketone (MEK), methyl isobutyl ketone (MIBK), diisobutyl ketone (DIBK), methyl isopropyl ketone (MIPK), cyclohexanone, cyclopentanone (CPN), cycloheptanone, and acetone.

Examples of glycol ether-based solvents include methyl cellosolve, butyl cellosolve, ethylene glycol mono t-butyl ether (ETB), propylene glycol monomethyl ether (PGME), pro-ether-based solvent pyrene glycol monomethyl ether acetate (PGMEA), and 3-methoxy-3-methyl-1-butanol (MMB).

Examples of other solvents include halogen-based solvents containing chlorine or fluorine, such as chloroform, chlorobenzene, and fluoroalkyl ether. One of these solvents may be used alone or one or more thereof may be used in combination.

The organic solvent can be appropriately selected depending on conditions such as pollution, solubility, volatility, attack on a substrate or a base, a film formation device and a film formation method.

In the present invention, by reducing the solubility of a photosensitive surface treatment layer, it becomes insoluble in a washing solution, a plating solution, a solvent used in multilayer film formation and the like, and washing resistance and process resistance can be improved in the wiring and laminating step.

In the case of the photosensitive surface treating agent containing the compound represented by Formula (M1), in order to improve the reactivity between a base coating agent and a photosensitive surface treating agent, or between molecules within a photosensitive surface treating agent, the contained solvent is preferably an alcohol-based, ether-based, or hydrocarbon-based solvent, particularly a hydrocarbon-based solvent, and among these, toluene is preferable.

In order to further increase the reactivity, any acidic or basic compound may be incorporated during film formation. It can be appropriately selected depending on film formation conditions, and acidic compounds such as hydrochloric acid, acetic acid, and nitric acid are particularly preferable, and among these, acetic acid is preferable.

In the case of the photosensitive surface treating agent containing the compound represented by Formula (P1), in consideration of the solubility and film formability, the contained solvent is preferably an ester-based or ketone-based solvent, particularly a ketone-based solvent, and among these, cyclopentanone is preferable.

The concentration of the compound represented by Formula (M1) or the polymer compound represented by Formula (P1) contained in the photosensitive surface treating agent can be appropriately selected depending on film formation conditions, and in consideration of storage stability and economical efficiency, the concentration is preferably 0.001 to 10 mass %, more preferably 0.01 to 2 mass %, and particularly preferably 0.1 to 0.3 mass %.

### <Pattern Forming Method>

A pattern forming method of the present embodiment includes a step of applying the photosensitive surface treating agent of the present embodiment onto a substrate to form a photosensitive resin film, a step of emitting predetermined pattern light to the photosensitive resin film to form an amine generation region in an exposure region, and a step of disposing an electroless plating catalyst in the amine generation region and performing electroless plating.

Hereinafter, the steps will be described with reference to the drawings.

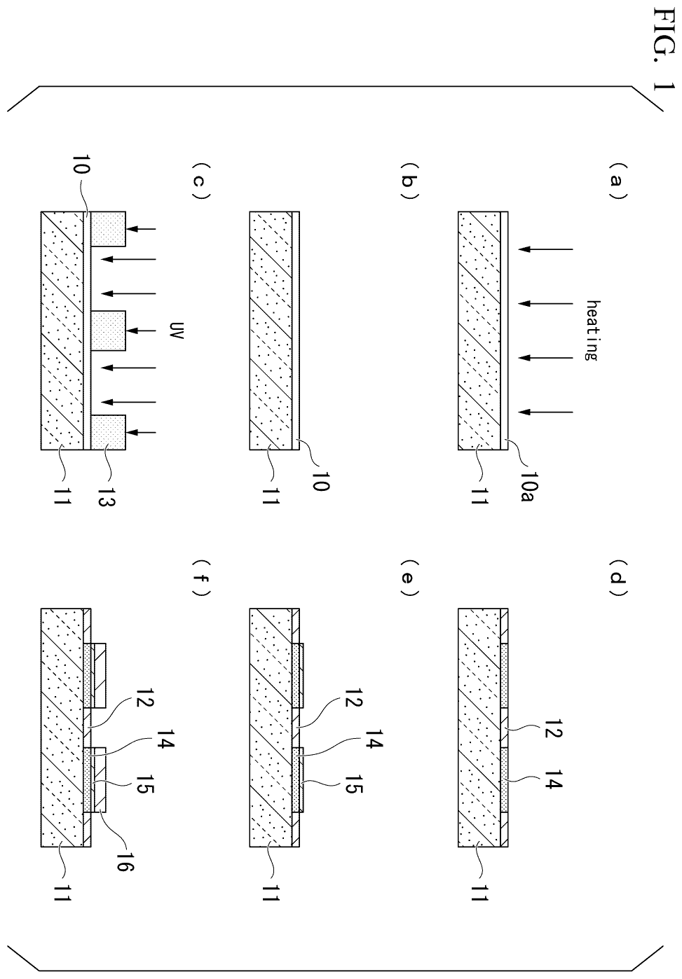

As shown in FIG. 1(a), a photosensitive surface treating agent 10a of the present embodiment is applied onto a substrate 11.

As the coating method, coating methods such as a spin coating method, a dip coating method, a die coating method, a spray coating method, a roll coating method, a microgravure method, a lip coating method, an inkjet method, applicator coating, and brush coating can be used. In addition, coating may be performed by a printing method such as flexographic printing or screen printing. In addition, an SAM film or an LB film may also be used.

Here, in this step, as shown in FIG. 1(a), for example, a treatment of drying the solvent by heat or decompression may also be added.

Thereby, as shown in FIG. 1(b), a photosensitive surface treating agent layer 10 is formed on the substrate 11.

Next, as shown in FIG. 1(c), a photomask 13 having an exposure region with a predetermined pattern is prepared. The exposure method is not limited to the method using a photomask, and methods such as projection exposure using an optical system such as a lens and a mirror, and maskless exposure using a spatial light modulation element and a laser beam can be used. Here, the photomask 13 may be provided to come into contact with the photosensitive surface treating agent layer 10 or may be provided not to come into contact therewith.

Then, as shown in FIG. 1(c), UV light is emitted to the photosensitive surface treating agent layer 10 through the photomask 13. Thereby, in the exposure region of the photomask 13, the photosensitive surface treating agent layer 10 is exposed.

As a result, as shown in FIG. 1(d), an amine-generated portion 14 is formed in an exposed part, and an amine-ungenerated portion 12 is formed in an unexposed part.

Examples of UV light include an i-line with a wavelength of 365 nm. In addition, the exposure amount and exposure time need not be sufficient for the deprotection to completely progress, and it is sufficient if some amines are generated.

Next, as shown in FIG. 1(e), an electroless plating catalyst is applied to the surface to form a catalyst layer 15. The electroless plating catalyst is a catalyst that reduces metal ions contained in a plating solution for electroless plating, and examples thereof include silver and palladium.

An amino group is exposed on the surface of the amine-generated portion 14. The amino group can capture and reduce the above electroless plating catalyst.

Therefore, the electroless plating catalyst is captured only on the amine-generated portion 14, and the catalyst layer 15 is formed. In addition, the electroless plating catalyst that can support an amino group can be used.

As shown in FIG. 1(f), an electroless plating treatment is performed to form a plating layer 16. Here, the plating layer 16 may be made of a material such as nickel-phosphorus (NiP), gold (Au), or copper (Cu).

In this step, the substrate 11 is immersed in an electroless plating bath to reduce metal ions on the surface of the catalyst and deposit the plating layer 16. In this case, since the catalyst layer 15 that supports a sufficient amount of a catalyst is formed on the surface of the amine-generated portion 14, the plating layer 16 can be selectively deposited only on the amine-generated portion 14.

By the above step, it is possible to form a wiring pattern on a predetermined substrate using the photosensitive surface treating agent of the present embodiment.

### <Method of Producing Transistor>

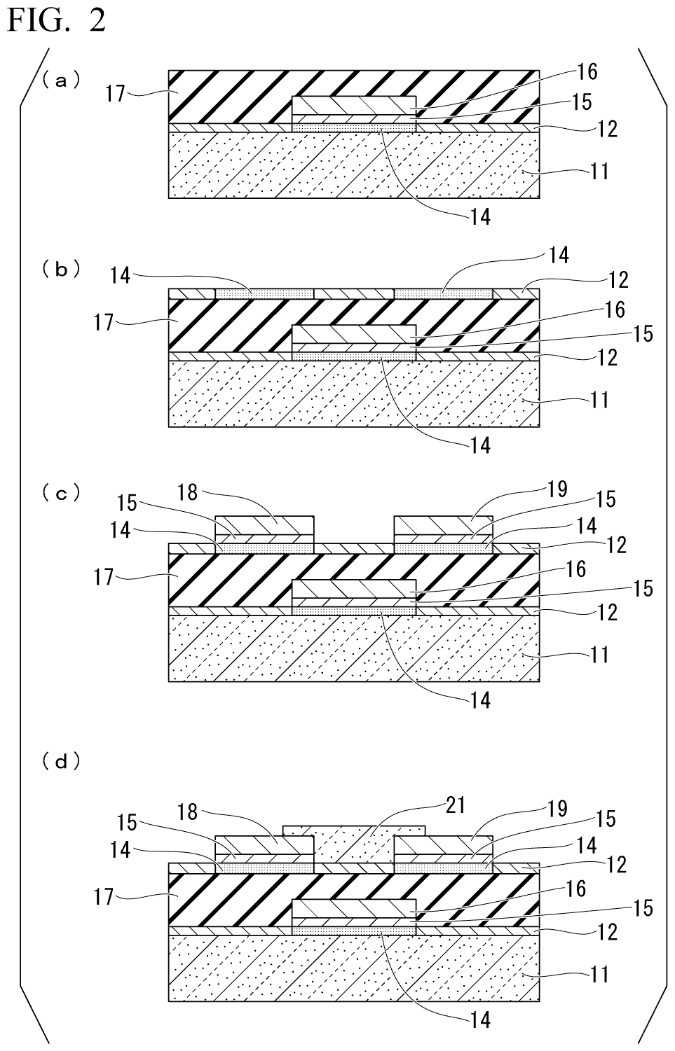

In addition, a method of producing a transistor in which the plating layer 16 obtained by the above <Pattern forming method> is used as a gate electrode will be described with reference to FIG. 2.

As shown in FIG. 2(a), an insulator layer 17 is formed by a known method to cover the plating layer 16 with an electroless plating pattern formed by the above pattern forming method and the amine-ungenerated portion 12. The insulator layer 17 may be formed by using, for example, a coating solution in which one or more resins of a UV-curable acrylic resin, an epoxy resin, an ene-thiol resin, a silicone resin and the like are dissolved in an organic solvent and applying the coating solution. When ultraviolet rays are emitted to a coating film through a mask having an opening corresponding to the region in which the insulator layer 17 is to be formed, the insulator layer 17 can be formed into a desired pattern. Here, before the insulator layer 17 is formed, the amine-ungenerated portion 12 may be removed as necessary.

As shown in FIG. 2(b), the photosensitive surface treating agent layer 10 is formed on the insulator layer 17 in the same manner as in the above electroless plating pattern forming method, and the amine-generated portion 14 is formed in a portion in which a source electrode and a drain electrode are formed.

As shown in FIG. 2(c), in the same manner as in the above pattern forming method, the electroless plating catalyst is supported on the amine-generated portion 14, the catalyst layer 15 is formed, and electroless plating is then performed to form a plating layer 18 (source electrode) and a plating layer 19 (drain electrode). Here, the plating layers 18 and 19 may be made of a material such as nickel-phosphorus (NiP) or copper (Cu), but may be made of a material different from that of the plating layer 16 (gate electrode), and a different metal such as gold (Au) may be deposited on the surface of nickel-phosphorus (NiP) or copper (Cu), for example, by performing electroless gold plating.

As shown in FIG. 2(d), a semiconductor layer 21 is formed between the plating layer 18 (source electrode) and the plating layer 19 (drain electrode).

For example, the semiconductor layer 21 may be formed by preparing a solution obtained by dissolving an organic semiconductor material soluble in an organic solvent such as TIPS pentacene (6,13-Bis(triisopropylsilylethynyl) pentacene) in the organic solvent, applying the solution between the plating layer 18 (source electrode) and the plating layer 19 (drain electrode) and performing drying.

In addition, the semiconductor layer 21 may be formed by adding one or more types of insulating polymers such as polystyrene (PS) or polymethyl methacrylate (PMMA) to the solution, applying a solution containing the insulating polymers, and performing drying.

When the semiconductor layer 21 is formed in this manner, the insulating polymer is concentrated and formed below the semiconductor layer 21 (the side of the insulator layer 17). When there is a polar group such as an amino group at the interface between the organic semiconductor and the insulator layer, transistor properties tend to deteriorate, but when the organic semiconductor is provided via the above insulating polymer, it is possible to prevent transistor properties from deteriorating. As described above, it is possible to produce a transistor.

According to the above method, there is no need to provide a separate chemical resist or the like in the UV exposure step, and the step can be simplified using only a photomask. Therefore, it is needless to say that there is no need for a step of removing the resist layer. In addition, due to the catalyst reduction ability of the amino group, it is possible to omit a catalyst activation treatment step that is generally required, and high-definition patterning can be performed while achieving significant cost reduction and time saving. In addition, since the dip coating method can be used, it can also be used in the roll-to-roll step with significantly favorable compatibility.

Here, the structure of the transistor is not particularly limited, and can be appropriately selected depending on the purpose. For example, a top-contact/bottom-gate type transistor, a top-contact/top-gate type transistor, and a bottom-contact/top-gate type transistor may be produced in the same manner.

### <Laminate>

The present embodiment is a laminate containing the photosensitive surface treating agent of the present embodiment.

The laminate of the present embodiment is a laminate in which a substrate and a metal pattern are laminated, and contains a photosensitive surface treating agent in an unexposed part in which no pattern is formed.

### <Transistor>

The present embodiment is a transistor containing the photosensitive surface treating agent of the present embodiment.

The laminate of the present embodiment is a transistor having a laminate in which a substrate and a metal pattern are laminated, and contains a photosensitive surface treating agent in an unexposed part in which no pattern is formed.

### EXAMPLES

The present invention will be described below in more detail with reference to examples, but the present invention is not limited to the following examples.

### Example 1

By the following reaction, 1-(4,5-dimethoxy-2-nitrophenyl)-2-methylpropanol was synthesized.

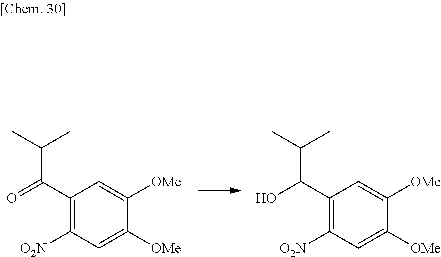 [SMILES: COc1cc(C(=O)C(C)C)c([N+](=O)[O-])cc1OC ; COc1cc(C(O)C(C)C)c([N+](=O)[O-])cc1OC]

20.0 g (79.0 mmol, 1.0 eq) of 1-(4,5-dimethoxy-2-nitrophenyl)-2-methylpropanone was put into a 1 L eggplant flask and dissolved in 200 mL of tetrahydrofuran (THF) and 100 mL of methanol, 4.48 g (118 mmol, 1.5 eq) of sodium tetraborohydride (NaBH₄) was gradually added at 0° C. (ice water), and the mixture was stirred at 0° C. for 30 min, and additionally stirred at room temperature for 2 h. After concentration using an evaporator, the mixture was diluted with ethyl acetate (300 mL), washed with H₂O (150 mL×3), dried using anhydrous magnesium sulfate (MgSO₄), filtered, concentrated, and vacuum-dried (in a water bath at 60° C.) to obtain 20.2 g (79.0 mmol, 100%) of a desired yellow viscous material product.

Rf=0.50 (hexane:ethyl acetate=1:1), UV254, raw material Rf=0.57

¹HNMR (CDCl₃,400 MHz)δ=0.96(6H,d,J=6.9 Hz)—CH(CH₃), 21.96-2.09(1H,m)—CH(CH₃), 22.23(1H,d,J=4.6 Hz)—OH3.95(3H,s)—OCH₃, 3.99(3H,s)—OCH₃, 5.27(1H,dd,J=4.6, 5.3 Hz)Ar—CH, 7.21(1H,s)Ar—H(6), 7.56(1H,s)Ar—H(3)

Next, by the following reaction, 1-(4,5-dimethoxy-2-nitrophenyl)-2-methylpropyl N-succinimidyl carbonate was synthesized.

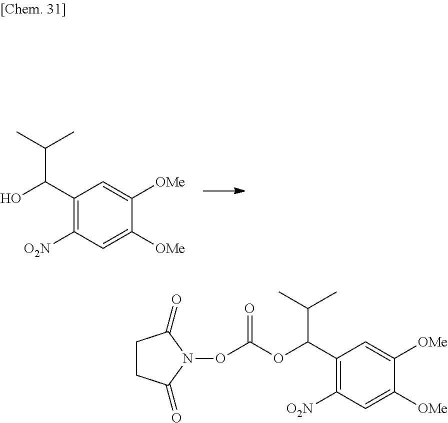 [SMILES: COc1cc(C(O)C(C)C)c([N+](=O)[O-])cc1OC ; COc1cc(C(OC(=O)ON2C(=O)CCC2=O)C(C)C)c([N+](=O)[O-])cc1OC]

20.2 g (79.0 mmol, 1.0 eq) of 1-(4,5-dimethoxy-2-nitrophenyl)-2-methylpropanol was put into a 500 mL eggplant flask and dissolved in 300 mL of anhydrous acetonitrile, 33 mL (238 mmol, 3.0 eq) of triethylamine and 30.3 g (118 mmol, 1.5 eq) of N,N′-disuccinimidyl carbonate (DSC) were added, and the mixture was stirred under a nitrogen atmosphere at room temperature for 20 h. After concentration using an evaporator, the mixture was diluted with chloroform (300 mL), sequentially washed with 0.5 N HCl (150 mL×3), and sat. NaClaq. (150 mL), dried using anhydrous magnesium sulfate (MgSO₄), filtered, concentrated, and vacuum-dried to obtain 31.8 g of a light yellow powder. The mixture was suspended in ethyl acetate (100 mL), filtered by suction, and vacuum-dried to obtain 20.1 g (53.1 mmol, 67%) of a light yellow white powder. (The filtrate was concentrated and then suspended again in ethyl acetate, filtered by suction, and vacuum-dried to obtain 6.62 g of a light brown solid).

Rf=0.35 (hexane:ethyl acetate=1:1), UV254 note: raw material Rf=0.50

¹H NMR (CDCl₃, 400 MHz)δ=1.04 (3H,d,J=6.9 Hz)—CH(CH₃)₂, 1.11(3H,d,J=7.0 Hz)—CH(CH₃)₂, 2.23-2.33(1H,m)—CH(CH₃)₂, 2.79(4H,s)—CH₂CH₂—, 3.96(3H,s)—OCH₃, 4.06(3H,s)—OCH₃, 6.41(1H,d,J-4.9 Hz)Ar—CH, 6.98(1H,s)Ar—H(6), 7.67(1H,s)gAr-H(3)

Next, by the following reaction, 1-(4,5-dimethoxy-2-nitrophenyl)-2-methylpropyl N-methyl-N-(3-(trimethoxysilyl) propyl) carbamate was synthesized.

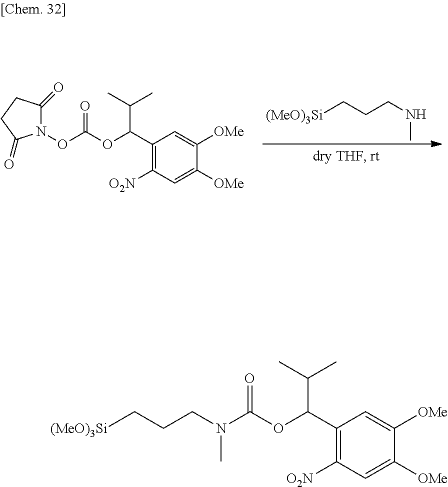

1.00 g (2.52 mmol, 1.0 eq) of 1-(4,5-dimethoxy-2-nitrophenyl)-2-methylpropyl N-succinimidyl carbonate, 20 mL of dry THF and 0.50 mL (2.52 mmol, 1.0 eq) of trimethoxy [3-(methylamino) propyl]silane were put into a 100 mL two-necked eggplant flask, and the mixture was stirred under a nitrogen atmosphere at room temperature for 2 hours. Since the starting raw material active carbonate remained on TLC, 0.50 mL (2.52 mmol, 1.0 eq) of trimethoxy [3-(methylamino) propyl]silane was additionally added, and the mixture was stirred for 1 hour. Since the reaction proceeded according to TLC, the reaction solution was concentrated and vacuum-dried to obtain a light yellow viscous material with a crude yield amount of 1.785 g. The light yellow viscous material was dissolved in chloroform and purified by silica gel column chromatography (φ=4.0 cm, h=15 cm, hexane:ethyl acetate:acetone:(MeO)₄Si=50:25:25:1). The purified product was concentrated and vacuum-dried on a water bath (60° C.) to remove (MeO)₄Si, and 1.089 g (2.29 mmol, 91%) of a desired light yellow viscous material product was obtained.

¹H-NMR(CDCl₃)400 MHz δ=0.61-0.66(m,2H), 1.01 (d, 3H, J=6.1 Hz), 1.05(d,3H,J=6.9 Hz), 1.60-1.72 (m, 2H), 2.17-2.22 (m, 1H), 2.87-3.02 (m, 3H), 3.22-3.39 (m, 2H), 3.58 (s, 9H), 3.94 (s, 3H), 3.95 (s, 3H), 6.24 (d, 1H, J=4.9 Hz), 6.89 (s, 1H), 7.62 (s, 1H)

¹³C-NMR(CDCl₃)100 MHz δ-6.26, 17.1, 19.6, 21.1, 33.3, 33.8, 34.8, 50.6, 51.5, 56.2, 56.3, 76.3, 108.0, 108.9, 132.3, 140.6, 147.7, 153.0, 155.5

Next, by the following reaction, cyclohexyl(4,5-dimethoxy-2-nitrophenyl)methylmethyl(3-(trimethoxysilyl)propyl)carba mate was synthesized.

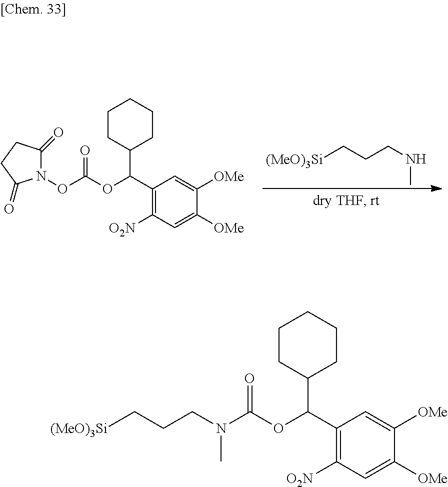

0.155 g (0.355 mmol, 1.0 eq) of cyclohexyl(4,5-dimethoxy-2-nitrophenyl)methyl(2,5-dioxopyrrolidin-1-yl)carbonate, 2 mL of anhydrous THF, and 85.0 μL (0.431 mmol, 1.2 eq) of trimethoxy [3-(methylamino) propyl]silane were put into a 10 mL two-necked test tube, and the mixture was stirred under an N₂ atmosphere at room temperature for 3 hours. The disappearance of the raw material was confirmed by TLC, and the reaction solution was concentrated, and vacuum-dried to obtain 0.247 g of a crude yellowish brown viscous material product. The product was purified by silica gel column chromatography (hexane:ethyl acetate:acetone:tetramethoxysilane=100:20:20:1, q=2, h=15), concentrated, and vacuum-dried (in a water bath at 60° C.). The product was rinsed with hexane, then concentrated, and vacuum-dried to obtain 0.074 g (0.144 mmol, 41%) of a desired yellow solid product.

¹H-NMR (CDCl₃) 400 MHz δ=0.50-0.66 (m, 2H), 1.00-1.40 (m, 5H), 1.50-1.85 (m, 6H), 2.93 (d, 3H, J=58.0 Hz), 3.10-3.45 (m, 2H), 3.56 (d, 9H, J=15.6 Hz), 3.93 (s, 3H), 3.95 (s, 3H), 6.25 (s, 1H), 6.87 (s, 1H), 7.60 (s, 1H)

¹³C-NMR (CDCl₃) 100 MHz δ=6.00, 6.55, 20.7, 21.6, 26.1, 26.3, 27.8, 29.8, 33.9, 34.8, 43.0, 50.6, 51.5, 51.5, 56.3, 56.3, 76.0, 76.1, 108.0, 109.1, 132.0, 140.6, 147.7, 153.0, 155.5

By the following reaction, 2-((tert-butoxycarbonyl)(methyl)amino)ethyl methacrylate (Boc-NMe-AEMA) was synthesized.

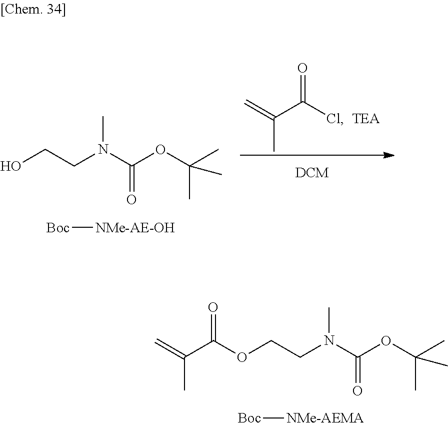

Under an argon atmosphere, 15 g (85.6 mmol, 1.0 eq.) of tert-butyl(2-hydroxyethyl)(methyl)carbamate (Boc-NMe-AE-OH), 75 ml of anhydrous dichloromethane, and 25.99 g (256.8 mmol, 3.0 eq.) of triethylamine were put into a 500 mL four-necked flask, and cooled on ice. A mixed solution containing 13.42 g (128.4 mmol, 1.5 eq.) of methacryloyl chloride and 75 ml of dichloromethane was added dropwise to the reaction solution at an internal temperature of 20° C. or lower over 5 minutes.

The reaction solution changed from a colorless and transparent solution to a light red suspension according to dropwise addition. The ice bath was removed, the mixture was stirred at room temperature for 1 hour, and the disappearance of the raw material was then confirmed by TLC (ethyl acetate/heptane=1/1, ninhydrin) and GC. 90 mL (90 mmol, 1.05 eq.) of a 1 M NaOH aqueous solution was put into the reaction solution to quench the reaction.

The organic layer was removed, concentrated under a reduced pressure at 40° C., and then diluted with 300 mL of heptane. The heptane solution was washed three times with 90 mL of a 1 M NaOH aqueous solution and once with 30 g of 20% saline. The organic layer was dehydrated with sodium sulfate, and then concentrated under a reduced pressure at 40° C. to obtain 21.7 g of a crude red-orange oil product.

This crude product was mixed with a crude product (Boc-NMe-AE-OH, 5 g added) obtained in a separate synthesis study using the same method, and diluted with 100 mL of heptane. The diluted solution was added to 150 g of a silica gel, and column purification (development:heptane only→ethyl acetate/heptane=⅕) was performed. 30 mg (equivalent to 1,000 ppm) of MEHQ was added to desired product fractions, and then concentrated under a reduced pressure to obtain a desired slightly yellow oil product.

yield amount 30.93 g, yield 97.1%

¹H-NMR (CDCl₃) 400 MHz δ=1.45 (s, 9H), 1.95 (s, 3H), 2.92 (m, 3H), 3.52 (m, 2H), 4.25 (m, 2H), 5.59 (s, 1H), 6.13 (s, 1H)

By the following reaction, 2-(methylamino)ethyl methacrylate trifluoroacetate (Boc-NMe-AEMA-TFAsalt) was synthesized.

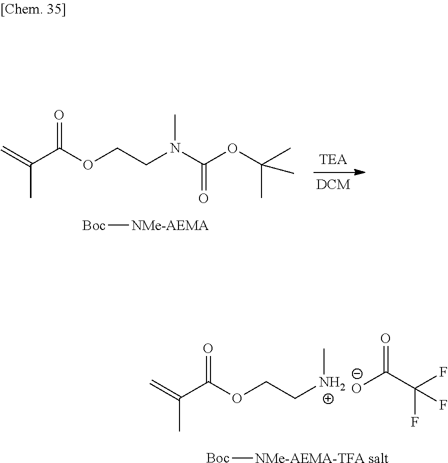

Under an argon atmosphere, 30.00 g (123.3 mmol, 1.0 eq.) of Boc-NMe-AEMA, 150 ml of dichloromethane, and 70.29 g (616.5 mmol, 5.0 eq.) of trifluoroacetic acid were put into a 300 mL eggplant flask at room temperature and stirred. The reaction solution turned slightly yellowish after trifluoroacetic acid was added.

After stirring overnight at room temperature, the disappearance of the raw material was confirmed by TLC (methanol/dichloromethane= 1/10, ninhydrin) and NMR. The reaction solution was concentrated under a reduced pressure at 45° C. to 63.0 g (crude yield 200%), and diluted with 60 mL of dichloromethane. The diluted solution was added to 300 g of a silica gel, and column purification (development:dichloromethane only→methanol/dichloromethane=½) was performed. 30 mg (equivalent to 1,000 ppm) of MEHQ was added to desired product fractions, and then concentrated under a reduced pressure to obtain a desired slightly yellow oil product.

yield amount 28.16 g, yield 88.8%

¹H-NMR (CDCl₃) 400 MHz δ=1.93 (s, 3H), 2.75 (s, 3H), 3.31 (br, 2H), 4.47 (m, 2H), 5.64 (s, 1H), 6.66 (s, 1H), 9.69 (br, 2H)

By the following reaction, 2-(((1-(4,5-dimethoxy-2-nitrophenyl)-2-methylpropoxy) carbonyl)(methyl)amino)ethyl methacrylate (NMe-iPrNBC-AEMA) was synthesized.

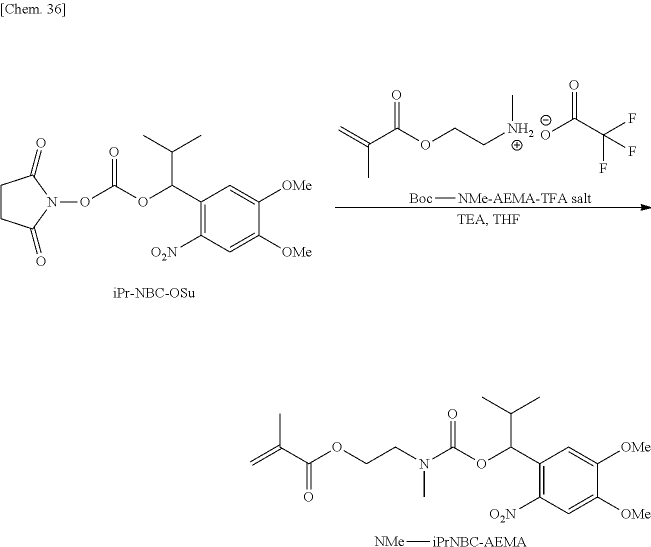

Under an argon atmosphere, 8 g (20.18 mmol) of iPrNBC-OSu, 288 ml of THF, and 3.5 ml (25.23 mmol, 1.25 eq) of TEA were put into a 500 ml four-necked flask to prepare a turbid and light yellow solution. A 20 wt % methanol solution containing 29.85 g of Boc-NMe-AEMA-TFAsalt was added dropwise to the solution. As the solution was added dropwise, the solution became gradually more turbid. The mixture was stirred at room temperature, and after 3.5 hours, the disappearance of the raw material was confirmed by TLC, and the reaction was completed. Distilled water (280 ml) and ethyl acetate (280 ml) were added to the reaction solution, and stirred, and the organic layer was separated. The aqueous layer was extracted with ethyl acetate, and all the separated organic layers were combined. The organic layer was washed twice with 5% NaCl aq. The organic layer was dehydrated with sodium sulfate, and solid components were removed and then concentrated under a reduced pressure at 30° C. The residue was diluted with ethyl acetate, and an insoluble solid component was filtered and then concentrated to obtain a yellow liquid (10.2 g). The liquid was diluted with ethyl acetate (20 ml) and filled into a silica gel column (160 g). The sample was purified by applying a gradient of 3/1->1/1->½ with a heptane/ethyl acetate eluent. When a crude product solution was developed with heptane/ethyl acetate=3/1, since a thin spot was confirmed near and just above the desired product (Rf=0.22), the column was eluted with a heptane/ethyl acetate gradient. Desired product fractions were concentrated to obtain a yellow liquid (5.20 g). The obtained yellow liquid was diluted with ethyl acetate, and MEHQ (0.52 mg, 100 ppm) was added and the mixture was then stored in a refrigerator.

yield amount 5.20 g, yield 60.7%

¹H-NMR (CDCl₃) 400 MHz δ=1.02 (m,6H), 1.90 (s, 3H), 2.21 (m, 1H), 3.00 (s, 3H), 3.51 (m, 3H), 3.94 (s, 6H), 4.30 (m, 2H), 5.55 (s, 1H), 6.05 (s, 1H), 6.25 (m, 1H), 6.90 (s, 1H), 7.60 (s, 1H)

By the following reaction, poly 2-(((1-(4,5-dimethoxy-2-nitrophenyl)-2-methylpropoxy)carbonyl)(methyl)amino)ethyl methacrylate (P-NMe-iPrNBC-AEMA) was synthesized.

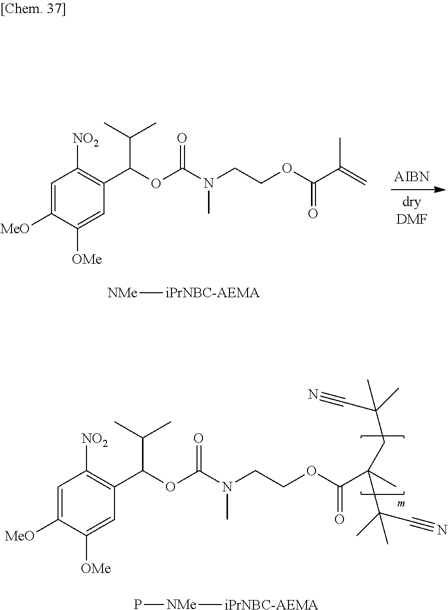

In a 50 mL eggplant flask, under argon, 2.45 g (5.77 mmol, 1.00 eq.) of NMe-iPrNBC-AEMA and 4 ml of DMF degassed for 30 minutes were added and dissolved (yellow solution). 47.5 mg (0.289 mmol, 0.05 eq.) of azobisisobutyronitrile AIBN was added thereto, the bath temperature was then raised to 65° C. in 30 minutes, and the mixture was heated and stirred at the same temperature for 36 hours. The completion of the reaction was determined by checking the progress of the reaction by NMR. The reaction solution was cooled and then added dropwise to methanol (60 mL) using a Pasteur, and the mixture was stirred for 20 minutes.

The obtained slurry solution was centrifuged (10,000 rpm, 10 min), the supernatant was then removed, methanol (40 mL) was added thereto, and the mixture was stirred by hand and then centrifuged (10,000 rpm, 10 min). The same operation was repeated once more, and the obtained solid was dissolved in chloroform. The mixture was added dropwise to methanol (60 mL) using a Pasteur, and stirred for 20 minutes. The obtained slurry solution was centrifuged (10,000 rpm, 10 min), the supernatant was then removed, methanol (40 mL) was added thereto, and the mixture was stirred by hand and then centrifuged (10,000 rpm, 10 min). The same operation was repeated once more and the obtained solid was then dried under a reduced pressure (60° C./<1 mmHg, 16 h) to obtain 1.89 g of a desired P-NMe-iPrNBC-AEMA.

¹H-NMR (CDCl₃) 400 MHz δ=0.80-0.99 (br.9H), 1.79-2.18 (br, 3H), 2.91-3.07 (br, 3H), 3.20-3.95 (br, 10H), 6.22 (br, 1H), 6.94 (br, 1H), 7.54 (br, 1H)

GPC number average molecular weight Mn=9041 The following polymer (P1)-A11 was synthesized.

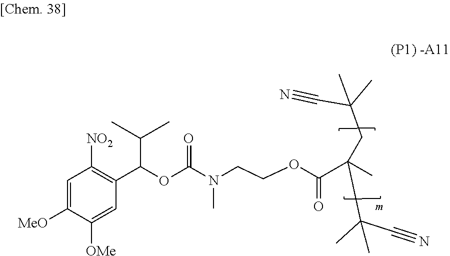

### Evaluation

### [Plated Wiring Production 1]

A film was formed on a substrate using a surface treating agent containing a polymer compound represented by Formula (P1)-A11 to produce a plated wiring.

Cyclopentanone was added to the polymer compound represented by Formula (P1)-A11 synthesized in Example 1 to adjust the concentration to 0.2 mass %, and thereby a photosensitive surface treating agent 1 was obtained.

The photosensitive surface treating agent 1 was applied onto a polyimide substrate (product name Upilex, commercially available from UBE Corporation) using a spin coater (MS-A150, commercially available from Mikasa Corporation) at 1,000 rpm. Then, drying was performed at 100° C. for 20 minutes, and a photosensitive surface treating agent layer was formed.

Next, the substrate in which the photosensitive surface treating agent layer was formed on the entire surface was exposed to light with a wavelength of 365 nm at 2,000 mJ/cm² through a photomask, the photosensitive surface treating agent layer was exposed to light, an amino group-generated portion was formed in the exposed part, and an amino group-ungenerated portion was formed in the unexposed part.

Next, the substrate was immersed in a catalyst colloidal solution for electroless plating (Melplate Activator 7331, commercially available from Meltex Inc.) at room temperature for 3 minutes, and a catalyst (Pd) was attached to the amine-generated portion. After the surface was washed with water, the substrate was immersed in an electroless plating solution (Melplate NI-867, commercially available from Meltex Inc.) at 73° C. for 1 minute to deposit nickel phosphorus on the catalyst, and thereby a fine plated wiring was produced.

### [Plated Wiring Production 2]

A plated wiring was produced in the same method as in the above [Plated wiring production 1] except that the substrate was changed to a quartz substrate (product name VIOSIL-SQ, commercially available from Shin-Etsu Chemical Co., Ltd.).

### [Evaluation of Plated Wiring]

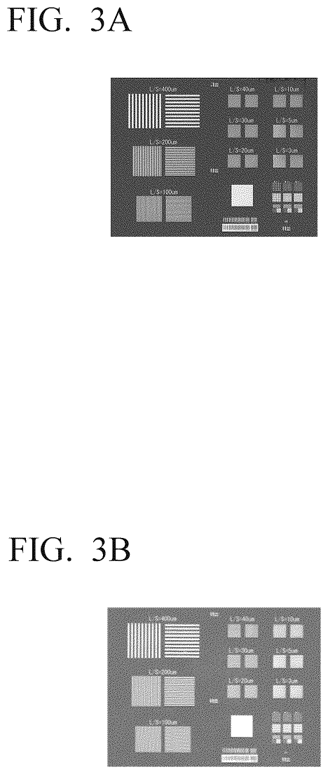

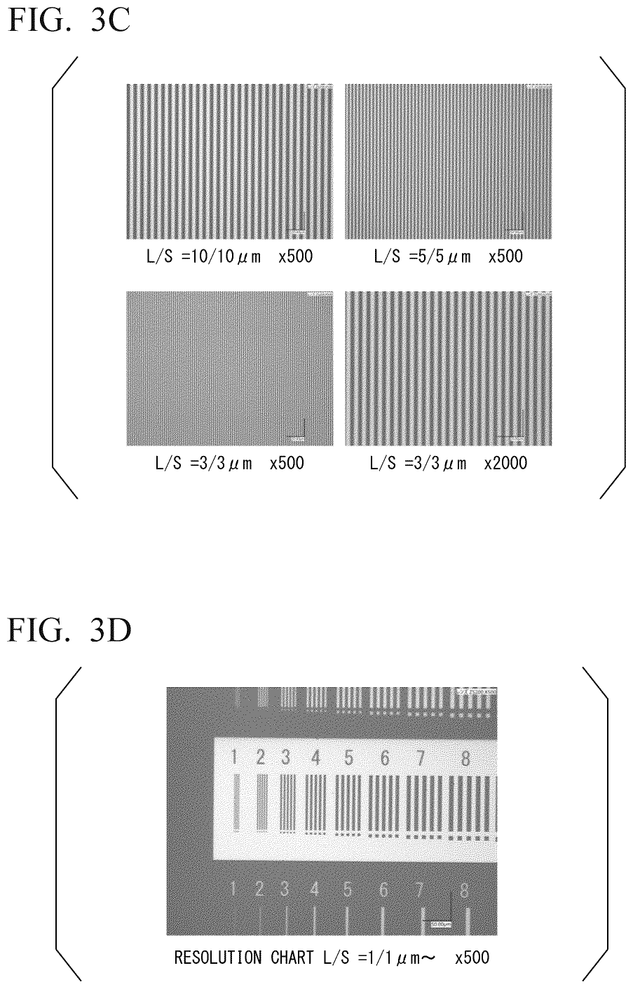

FIG. 3A to FIG. 3D show overall images of a polyimide substrate and a quartz substrate on which a plated wiring treatment was performed in examples, and optical microscope (VHX-7000, commercially available from Keyence Corporation) images. FIG. 3A shows overall images of resolution charts drawn on a polyimide substrate and a quartz substrate.

FIG. 3B shows optical microscope images of resolution charts drawn on a quartz substrate.

FIG. 3C shows optical microscope images of L/S=3/3 to 10/10 μm drawn on a quartz substrate.

FIG. 3D shows an optical microscope image of L/S=1/1 to 8/8 μm drawn on a quartz substrate.

From FIG. 3A to FIG. 3D, it was confirmed by visual observation and using a microscope that a high-definition and favorable plated wiring could be formed using a surface treating agent containing the polymer compound represented by Formula (P1)-A11.

<Evaluation of Photolysis Rate Constant k(s⁻¹) Using Model Compound>

The following compounds (1) to (7) were each dissolved in acetonitrile to prepare a 0.1 mM solution.

Light with a wavelength of 365 nm and an illuminance of 25 mW/cm² was emitted from an ultra-high pressure mercury lamp through a 365 nm bandpass filter and a water filter for 5, 10, 15, 20, 25, and 30 seconds, and HPLC measurement was performed.

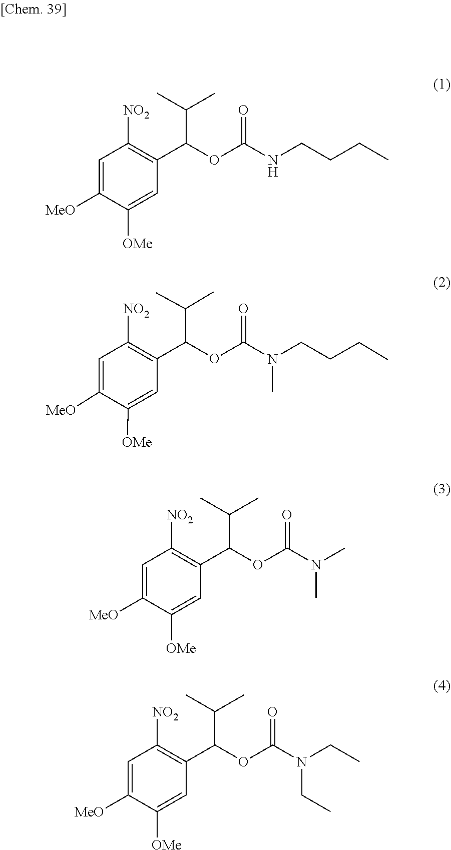 [SMILES: CCCCNC(=O)OC(c1cc(OC)c(OC)cc1[N+](=O)[O-])C(C)C ; CCCCN(C)C(=O)OC(c1cc(OC)c(OC)cc1[N+](=O)[O-])C(C)C ; COc1cc(C(OC(=O)N(C)C)C(C)C)c([N+](=O)[O-])cc1OC ; CCN(CC)C(=O)OC(c1cc(OC)c(OC)cc1[N+](=O)[O-])C(C)C]

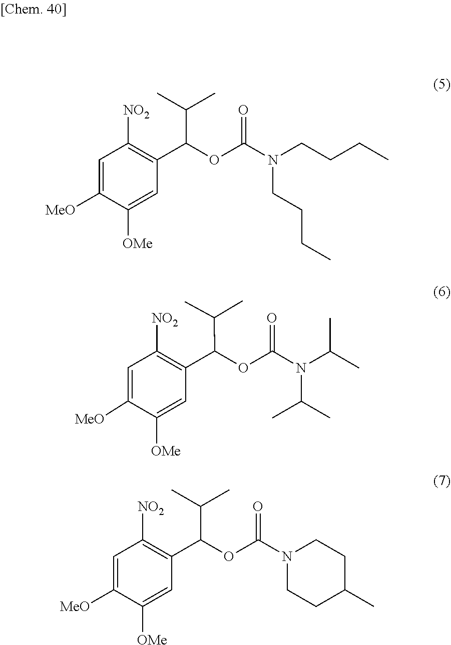

The peak area (S₀: area before light emission, St: area t seconds after light emission) of the raw material obtained by HPLC measurement was substituted into the following formula, and the photolysis rate constant k(s⁻¹) was determined from the reduction rate of the raw material. The results are shown in Table 1.

$$ln ( \frac{{S}_{t}}{{S}_{0}} ) = - kt \qquad [ Math . 1 ]$$

TABLE 1

| | k(s⁻¹) |
|---|---|
| Compound (1) | 0.041 |
| Compound (2) | 0.052 |
| Compound (3) | 0.048 |
| Compound (4) | 0.048 |
| Compound (5) | 0.044 |
| Compound (6) | 0.050 |
| Compound (7) | 0.046 |

It was confirmed that, among the compounds (1) to (7), the compounds (2) to (7) had a higher photolysis rate than the compound (1).

In the compound (1), the compound represented by Formula (M1) was a model compound in which the group corresponding to R¹ was a hydrogen atom. Based on the above results, it was confirmed that, when R¹ was a linear or branched alkyl group having 1 to 4 carbon atoms, the photolysis rate at which the nitrobenzyl group was eliminated was higher than that of the compound in which the group corresponding to R¹ was a hydrogen atom.

The compound (2) was a model compound of the polymer compound represented by Formula (P1)-A11. The compounds (3) to (7) had a photolysis rate constant equivalent to that of the compound (2). Therefore, it can be reasonably inferred that, even when the above exemplary example compounds (M1)-1 to (M1)-6 and polymer compounds (P1)-A2 to (P1)-A6 were used, the same effects as those obtained when the polymer compound represented by Formula (P1)-A11 was used were exhibited.

### REFERENCE SIGNS LIST

11 Substrate
10a Photosensitive surface treating agent
10 Photosensitive surface treating agent layer
13 Photomask
14 Amine-generated portion
12 Amine-ungenerated portion
15 Catalyst layer
16 Plating layer
17 Insulator layer
18 Plating layer (source electrode)
19 Plating layer (drain electrode)
21 Semiconductor layer

1-14. (canceled)

15. A photosensitive surface treating agent comprising a compound represented by the following Formula (M1): 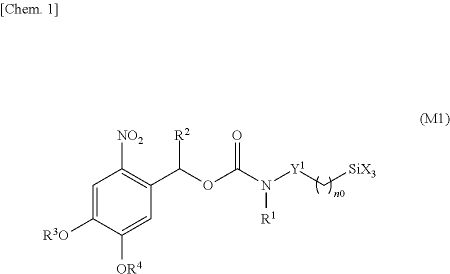
wherein (in Formula (M1), R¹ is a linear, branched or cyclic alkyl group having 1 to 6 carbon atoms, Y¹ is a linear or branched alkylene group having 1 to 4 carbon atoms or a single bond, and the terminal carbon atom of the alkyl group for R¹ may be bonded to a carbon atom constituting the alkylene group for Y¹, and R¹ and Y¹ may form a ring,
R² is a hydrogen atom or an alkyl group having 1 to 6 carbon atoms, R³ and R⁴ are each independently an alkyl group having 1 to 3 carbon atoms, n0 is an integer of 0 or more, and X is a halogen atom or an alkoxy group).

16. A photosensitive surface treating agent comprising a polymer compound represented by the following Formula (P1): 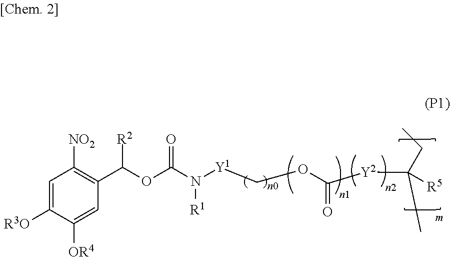
wherein (in Formula (P1), R¹ is a linear, branched or cyclic alkyl group having 1 to 6 carbon atoms, Y¹ is a linear or branched alkylene group having 1 to 4 carbon atoms or a single bond, Y² is a group obtained by removing two hydrogen atoms from an aromatic ring having 6 to 15 carbon atoms, and the terminal carbon atom of the alkyl group for R¹ may be bonded to a carbon atom constituting the alkylene group for Y¹, and R¹ and Y¹ may form a ring,
R² is a hydrogen atom or an alkyl group having 1 to 6 carbon atoms, R³ and R⁴ are each independently an alkyl group having 1 to 3 carbon atoms, R⁵ is a hydrogen atom or a methyl group, n0, n1, and n2 are each independently an integer of 0 or more, and m is a natural number).

17. The photosensitive surface treating agent according to claim 16, further comprising a ketone-based solvent.

18. The photosensitive surface treating agent according to claim 16,
wherein the polymer compound has a number average molecular weight of 2,000 to 40,000.

19. The photosensitive surface treating agent according to claim 17,
wherein the polymer compound has a number average molecular weight of 2,000 to 40,000.

20. The photosensitive surface treating agent according to claim 16,
wherein at least one terminal of the polymer compound is a substituent represented by the following General Formula (1x):

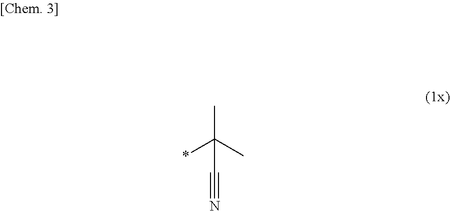

21. The photosensitive surface treating agent according to claim 17,
wherein at least one terminal of the polymer compound is a substituent represented by the following General Formula (1x):

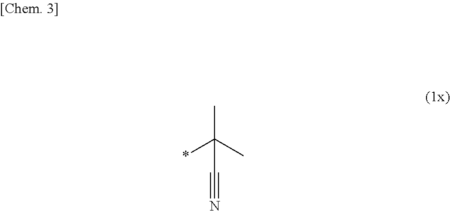

22. A laminate comprising the photosensitive surface treating agent according to claim 15.

23. A laminate comprising the photosensitive surface treating agent according to claim 16.

24. A pattern formation substrate having a surface that is chemically modified using the photosensitive surface treating agent according to claim 15.

25. A pattern formation substrate having a surface that is chemically modified using the photosensitive surface treating agent according to claim 16.

26. A transistor comprising the photosensitive surface treating agent according to claim 15.

27. A transistor comprising the photosensitive surface treating agent according to claim 16.

28. A pattern forming method, comprising:
a step of applying the photosensitive surface treating agent according to claim 15 onto a substrate to form a photosensitive resin film;
a step of emitting predetermined pattern light to the photosensitive resin film; and
a step of performing electroless plating on at least a part of the region emitted with the predetermined pattern light.

29. A pattern forming method, comprising:
a step of applying the photosensitive surface treating agent according to claim 16 onto a substrate to form a photosensitive resin film;
a step of emitting predetermined pattern light to the photosensitive resin film; and
a step of performing electroless plating on at least a part of the region emitted with the predetermined pattern light.

30. A pattern forming method, comprising:
a step of applying the photosensitive surface treating agent according to claim 15 onto a substrate to form a photosensitive resin film;
a step of emitting predetermined pattern light to the photosensitive resin film; and
a step of disposing an electroless plating catalyst in at least a part of the region emitted with the predetermined pattern light and performing electroless plating.

31. A pattern forming method, comprising:
a step of applying the photosensitive surface treating agent according to claim 16 onto a substrate to form a photosensitive resin film;
a step of emitting predetermined pattern light to the photosensitive resin film; and
a step of disposing an electroless plating catalyst in at least a part of the region emitted with the predetermined pattern light and performing electroless plating.

32. A pattern forming method, comprising:
a step of applying the photosensitive surface treating agent according to claim 15 onto a substrate to form a photosensitive resin film;
a step of emitting predetermined pattern light to the photosensitive resin film to form an amine generation region in an exposure region; and
a step of disposing an electroless plating catalyst in the amine generation region and performing electroless plating.

33. A pattern forming method, comprising:
a step of applying the photosensitive surface treating agent according to claim 16 onto a substrate to form a photosensitive resin film;
a step of emitting predetermined pattern light to the photosensitive resin film to form an amine generation region in an exposure region; and
a step of disposing an electroless plating catalyst in the amine generation region and performing electroless plating.

34. A method of producing a transistor, comprising
a step of forming at least one of a source electrode, a drain electrode, and a gate electrode by the pattern forming method according to claim 28.

35. A method of producing a transistor, comprising
a step of forming at least one of a source electrode, a drain electrode, and a gate electrode by the pattern forming method according to claim 29.

36. A method of producing a transistor, comprising
a step of forming at least one of a source electrode, a drain electrode, and a gate electrode by the pattern forming method according to claim 30.

37. A method of producing a transistor, comprising
a step of forming at least one of a source electrode, a drain electrode, and a gate electrode by the pattern forming method according to claim 31.

38. A transistor comprising a compound represented by the following Formula (M1) or a polymer compound represented by the following Formula (P1): 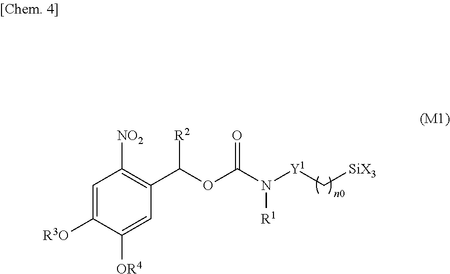
wherein (in Formula (M1), R¹ is a linear, branched or cyclic alkyl group having 1 to 6 carbon atoms, Y¹ is a linear or branched alkylene group having 1 to 4 carbon atoms or a single bond, and the terminal carbon atom of the alkyl group for R¹ may be bonded to a carbon atom constituting the alkylene group for Y¹, and R¹ and Y¹ may form a ring,
R² is a hydrogen atom or an alkyl group having 1 to 6 carbon atoms, R³ and R⁴ are each independently an alkyl group having 1 to 3 carbon atoms, n0 is an integer of 0 or more, and X is a halogen atom or an alkoxy group). 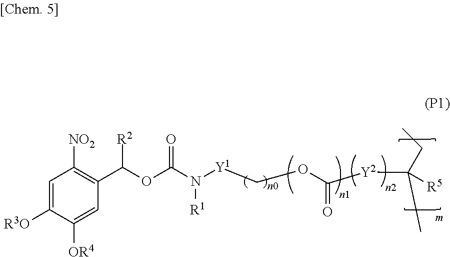
wherein (in Formula (P1), R¹ is a linear, branched or cyclic alkyl group having 1 to 6 carbon atoms, Y¹ is a linear or branched alkylene group having 1 to 4 carbon atoms or a single bond, Y² is a group obtained by removing two hydrogen atoms from an aromatic ring having 6 to 15 carbon atoms, and the terminal carbon atom of the alkyl group for R¹ may be bonded to a carbon atom constituting the alkylene group for Y¹, and R¹ and Y¹ may form a ring,
R² is a hydrogen atom or an alkyl group having 1 to 6 carbon atoms, R³ and R⁴ are each independently an alkyl group having 1 to 3 carbon atoms, R⁵ is a hydrogen atom or a methyl group, n0, n1, and n2 are each independently an integer of 0 or more, and m is a natural number).

39. The transistor according to claim 38,
wherein the compound or polymer compound has a portion in which at least some nitrobenzyl groups are eliminated and amino groups are generated.
